(19) United States
(12) Patent Application Publication
(10) Pub. No.: US 2012/0302030 A1
(43) Pub. Date: Nov. 29, 2012

(54) METHOD OF FABRICATING A DEEP TRENCH DEVICE

(76) Inventors: Hsiu-Chun Lee, Taipei City (TW); Yi-Nan Chen, Taipei City (TW); Hsien-Wen Liu, Taoyuan County (TW)

(21) Appl. No.: 13/118,451

(22) Filed: May 29, 2011

(51) Int. Cl. H01L 21/02; H01L 21/28

(52) U.S. Cl. 438/386; 438/675; 257/E21.158; 257/E21.008

(57) ABSTRACT

A method of fabricating a deep trench capacitor includes the steps as follows. Firstly, a substrate having a trench therein is provided. Then, a bottom electrode is formed in the substrate around the trench. Later, a capacitor dielectric layer is formed to surround an inner sidewall of the trench. After that, a first conductive layer is form to fill up the trench. Subsequently, a material layer is formed on the substrate. Later, a hole is formed in the material layer, wherein the hole is directly above the trench. Finally, a second conductive layer is form to fill in the hole.

### BACKGROUND OF THE INVENTION

1. Field of the Invention

The present invention relates generally to the semiconductor processing. More particularly, the present invention relates to a method of forming a deep trench device.

2. Description of the Prior Art

Trench structures have several uses in semiconductor device technology. Such uses include isolation structures, control electrode structures, capacitor structures, etc. To minimize the size of the semiconductor device, deep trenches with higher aspect ratio are needed.

Typically, to form a high-aspect-ratio deep trench in a silicon substrate, a hard mask is first deposited on the silicon substrate. Thereafter, a lithographic process is carried out to transfer a deep trench pattern onto the hard mask. After the hard mask is patterned, an etching process is then performed to etch the silicon substrate, thereby forming the deep trench.

However, the conventional method for forming the deep trench suffers from several drawbacks. The difference of an etching selectivity of the hard mask and of the silicon substrate is not high enough, which leads to the profile control problem during the formation of the deep trench in the silicon substrate. Therefore, there is a strong need to provide a novel method for forming a deep trench with high aspect ratio.

### SUMMARY OF THE INVENTION

The present invention addresses the needs described above by providing an economical and simple method of forming a deep trench device.

According to one aspect, a method of fabricating a deep trench device is provided. The method includes the steps as follows. Firstly, a substrate having a trench therein is provided. Next, a first material layer is formed to fill up the trench. Then, a second material layer is formed to cover the substrate and the first material layer. Later, a hole within the second material layer is formed, wherein the hole is directly on the trench. Finally, a third material layer is formed to fill in the hole.

According to another aspect, a method of fabricating a deep trench capacitor includes the steps as follows. Firstly, a substrate having a trench therein is provided. Then, a bottom electrode is formed in the substrate around the trench. Later, a capacitor dielectric layer is formed to surround an inner sidewall of the trench. After that, a first conductive layer is form to fill up the trench. Subsequently, a material layer is formed on the substrate. Later, a hole is formed in the material layer, wherein the hole is directly above the trench. Finally, a second conductive layer is form to fill in the hole.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute apart of this specification. The drawings illustrate some of the embodiments and, together with the description, serve to explain their principles. In the drawings:

FIG. 1 to FIG. 6 are schematic diagrams depict a method of fabricating a deep trench device according to a first preferred embodiment of the present invention.

FIGS. 1-2 and FIGS. 7-10 are schematic diagrams depict a method of fabricating a deep trench device according to a second preferred embodiment of the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following detailed description, reference is made to the accompanying drawings, which form a part hereof, and in which is shown by way of illustration specific examples in which the embodiments may be practiced. These embodiments are described in sufficient detail to enable those skilled in the art to practice them, and it is to be understood that other embodiments may be utilized and that structural, logical and electrical changes may be made without departing from the described embodiments. The following detailed description is, therefore, not to be taken in a limiting sense, and the included embodiments are defined by the appended claims.

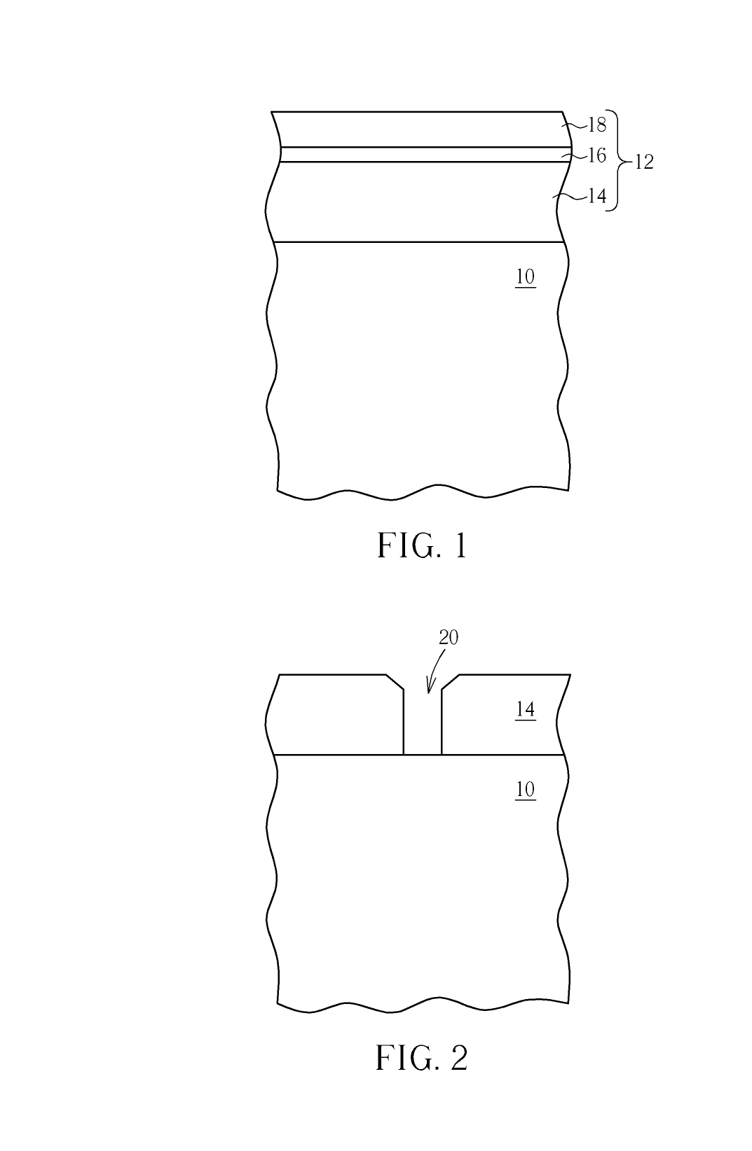

FIG. 1 to FIG. 6 are schematic diagrams depict a method of fabricating a deep trench capacitor according to a first preferred embodiment of the present invention. As shown in FIG. 1, a substrate 10 covered by a first mask layer 12 is provided. The first mask layer may include a boro-silicate glass (BSG) layer 14, an anti-reflective coating 16, a photoresist layer 18 disposed from bottom to top. As the term is used herein, “substrate” refers to any construction comprising the semiconductor material, including, but not limited to, bulk semiconductive materials, such as a semiconductive wafer, and semiconductive material layers (either alone or in assemblies comprising other materials). As shown in FIG. 2, a lithographic process is performed to pattern the first mask layer 12. For example, Firstly, the photoresist layer 18 and the anti-reflective coating 16 are patterned. Then, the BSG layer 14 is etched to form a trench pattern 20 by taking the photoresist layer 18 and the anti-reflective coating 16 as a mask. Later, the photoresist layer 18 and the anti-reflective coating 16 are removed.

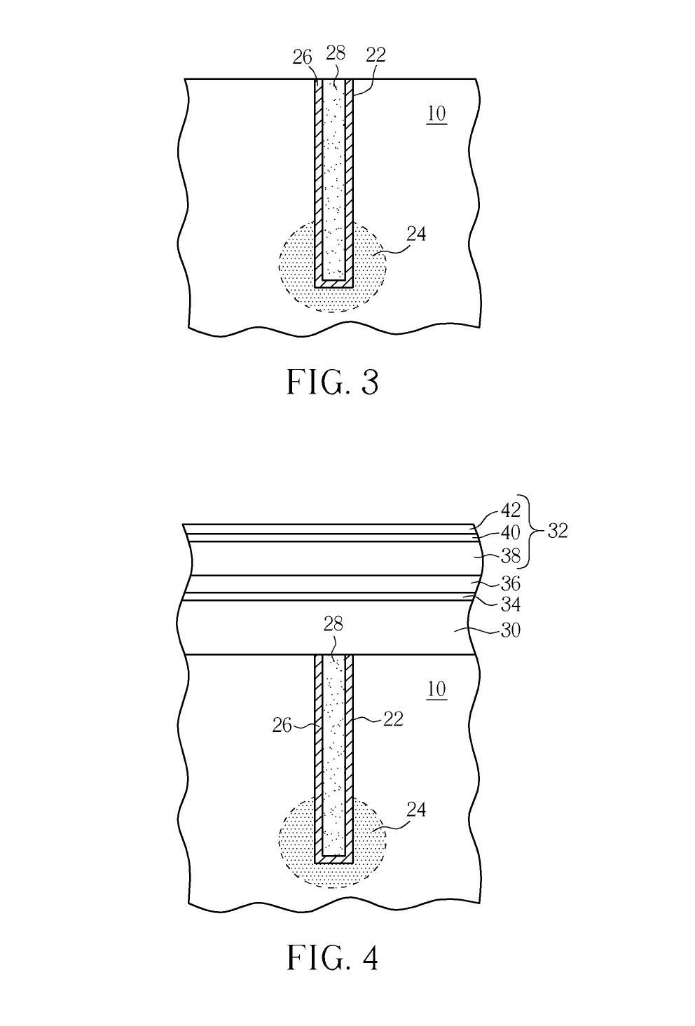

As shown in FIG. 3, the substrate 10 is etched to form a trench 22 in the substrate 10 by taking the BSG layer 14 as a mask. Subsequently, the BSG layer 14 is removed. Next, a gas diffusion process is performed to form a bottom electrode 24 in the substrate 10 around the bottom of the trench 22. After that, a capacitor dielectric layer 26 is formed along the inner sidewall of the trench 22. Later, a first conductive layer 28 such as polysilicon is filled into the trench 22.

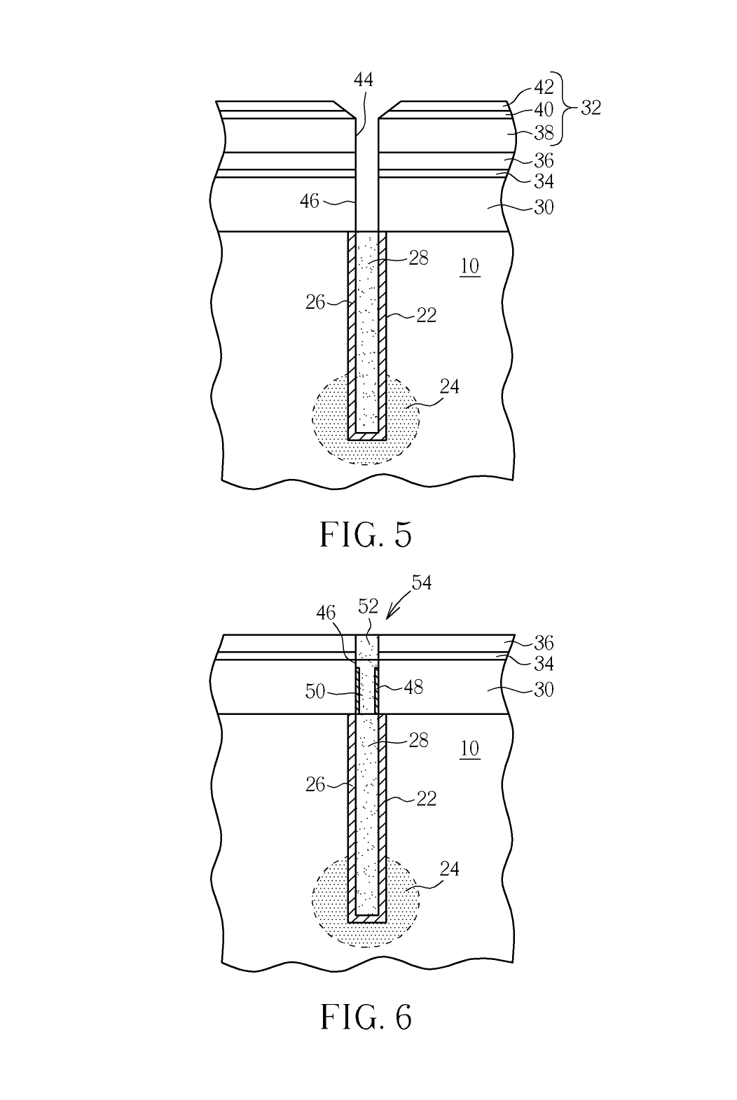

As shown in FIG. 4, a material layer 30 such as an epitaxial silicon layer is formed on the substrate 10. Then, a pad silicon oxide layer 34, a pad silicon nitride layer 36 and a second mask layer 32 are formed on the material layer 30. The second mask layer 32 may include a BSG layer 38, an anti-reflective coating 40, a photoresist layer 42 disposed from bottom to top. As shown in FIG. 5, the photoresist layer 42, the anti-reflective coating 40 and the BSG layer 38 are patterned to form a hole pattern 44 therein. Then, the pad silicon nitride layer 36, the pad silicon oxide layer 34 and the material layer 30 are etched to form a hole 46 within the pad silicon nitride layer 36, the pad silicon oxide layer 34 and the material layer 30 by taking the patterned the photoresist layer 42, the anti-reflective coating 40 and the BSG layer 38 as a mask. Later, the patterned the photoresist layer 42, the anti-reflective coating 40 and the BSG layer 38 are removed. The hole 46 is connected to the trench 22.

As shown in FIG. 6, a collar oxide 48 is form around the inner sidewall of the hole 46. Then, a second conductive layer 50 such as polysilicon is filled into the hole 46 partly. The top surface of the second conductive layer 50 is aligned with the top surface of the material layer 30. After that, a third conductive layer 52 such as polysilicon is filled in the hole 46, and the third conductive layer 52 is disposed on the second conductive layer 50. The first conductive layer 28 serves as a top electrode. Now, a deep trench capacitor 54 of the present invention is completed.

FIGS. 1-2 and FIGS. 7-10 are schematic diagrams depict a method of fabricating a deep trench device according to a second preferred embodiment of the present invention, wherein like numbered numerals designate similar or the same parts, regions or elements.

Firstly, as shown in FIG. 1, a substrate 10 covered with a first mask layer 12 is provided. The first mask layer 12 may include a BSG layer 14, an anti-reflective coating 16, a photoresist layer 18 disposed from bottom to top. Then, as shown in FIG. 2, the anti-reflective coating 16 and a photoresist layer 18 are patterned. Then, the BSG layer 14 is etched to form a trench pattern 20 by taking the anti-reflective coating 16 and the photoresist layer 18 as a mask. Later, the photoresist layer 18 and the anti-reflective coating 16 are removed.

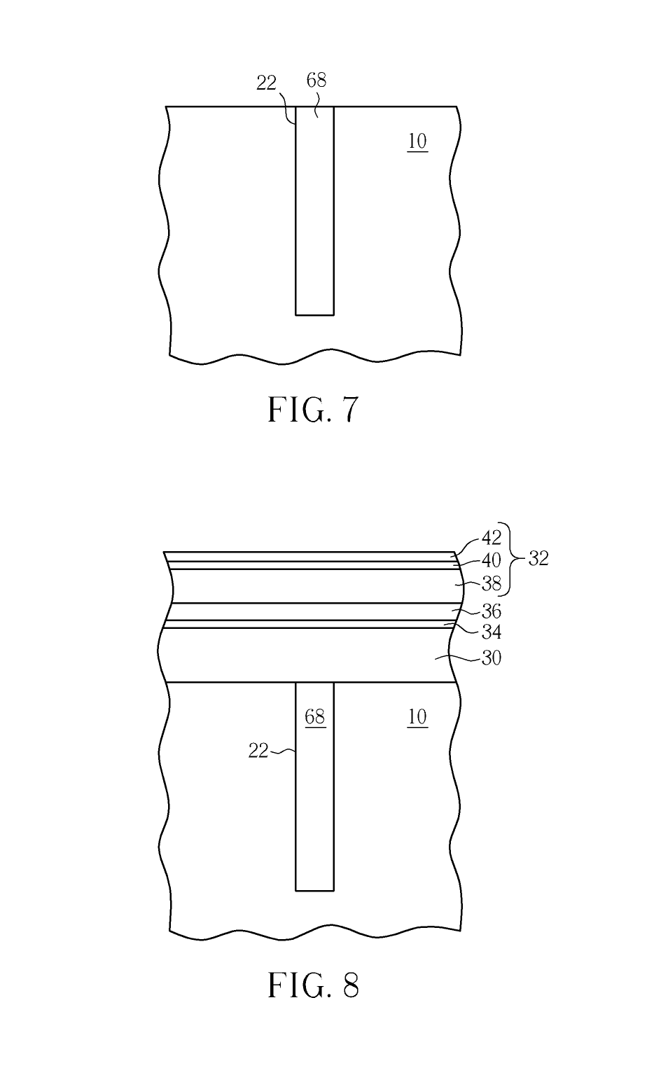

As shown in FIG. 7, the substrate 10 is etched to form a trench 22 therein by taking the BSG layer 14 as a mask. Then, the BSG layer 14 is removed. Next, a material layer 68 is filled into the trench 22. The material layer 68 can be a conductive layer, an insulation layer, or combinations thereof. The material layer 68 is preferably polysilicon. As shown in FIG. 8, a material layer 30 is formed on the substrate 10. The material layer 30 is preferably epitaxial silicon but not limited to it. The material layer 30 may be an insulation material, or a conductive material.

Then, a second mask layer 32, and a pad silicon oxide layer 34, and a pad silicon nitride layer 36 are formed on the material layer 30. The second mask layer 32 may include a photoresist layer 42, an anti-reflective coating 40 and a BSG layer 38.

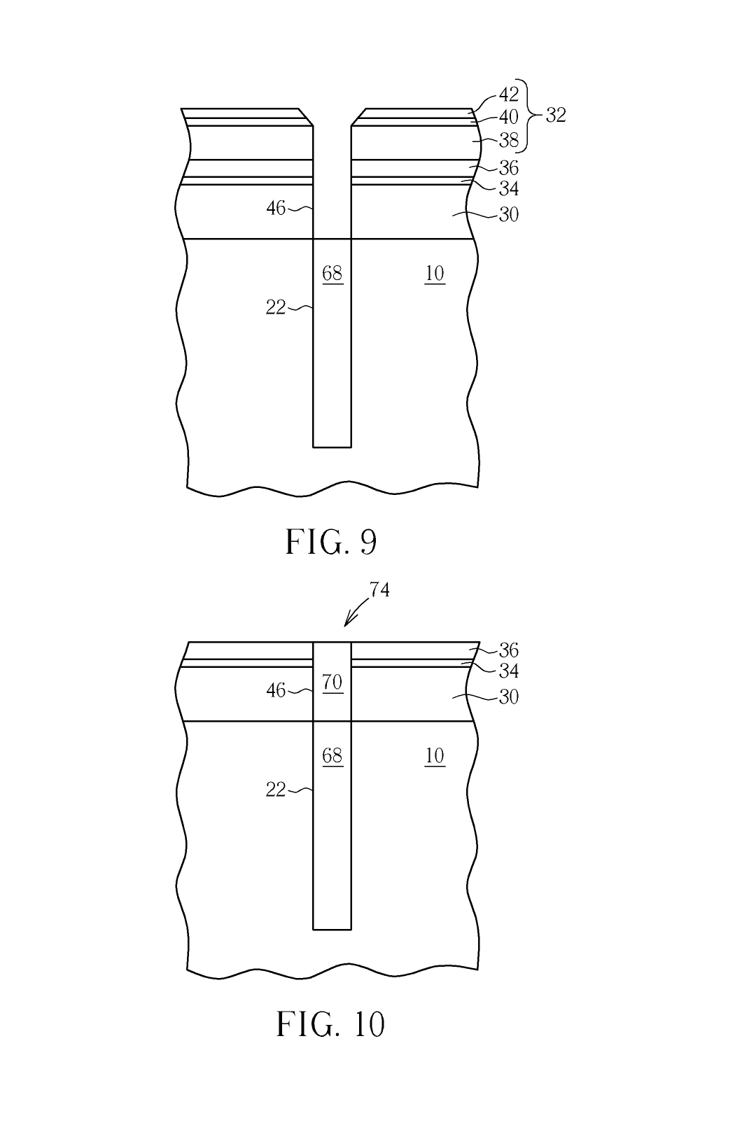

As shown in FIG. 9, the second mask layer 32 is patterned. Next, the pad silicon nitride layer 36, the pad silicon oxide layer 34 and the material layer 30 are etched to form a hole 46 within the pad silicon nitride layer 36, the pad silicon oxide layer 34 and the material layer 30 by taking the second mask layer 32 as a mask. The hole 46 is connected to the trench 22.

As shown in FIG. 10, the second mask layer 32 is removed. Then, a material layer 70 is filled into the hole 46. The material layer 70 can be a conductive layer, an insulation layer, or combinations thereof. Now, a deep trench device 74 of the present invention is completed.

The present invention fabricates a deep trench by firstly forming a trench in the substrate. Then, a hole is formed in an epitaxial layer above the trench. The hole and the trench compose a deep trench.

Those skilled in the art will readily observe that numerous modifications and alterations of the device and method may be made while retaining the teachings of the invention.

1. A method of fabricating a deep trench device, comprising:
providing a substrate (10) having a trench (22) therein;
forming a first material layer (68) to fill up the trench;
forming a second material layer (30) cover the substrate and the first material layer, wherein the second material layer is in direct contact with the first material layer;
forming a hole (46) within the second material layer, wherein the hole is directly on the trench; and
forming a third material layer (70) to fill in the hole.

2. The method of fabricating a deep trench device of claim 1, wherein the second material layer comprises epitaxial silicon.

3. The method of fabricating a deep trench device of claim 2, further comprising after forming the second material layer, forming a silicon oxide layer (34) and a silicon nitride layer (36) on the second material layer.

4. The method of fabricating a deep trench device of claim 3, wherein the hole extends into the silicon oxide layer and the silicon nitride layer.

5. The method of fabricating a deep trench device of claim 4, wherein the third material layer fill in the hole within the silicon oxide layer and the silicon nitride layer.

6. The method of fabricating a deep trench device of claim 1, further comprising before forming the third material layer, forming a collar oxide (48) around a sidewall of the hole within the second material layer.

7. The method of fabricating a deep trench device of claim 1, wherein the first material layer comprises polysilicon and the third material layer comprises polysilicon.

8. The method of fabricating a deep trench device of claim 1, wherein the substrate is a semiconductive substrate.

9. A method of fabricating a deep trench capacitor, comprising:
providing a substrate (10) having a trench (22) therein;
forming a bottom electrode (24) in the substrate around a bottom of the trench;
forming a capacitor dielectric layer (26) surrounding an inner sidewall of the trench;
forming a first conductive layer (28) fill up the trench;
forming a material layer (30) on the substrate, wherein the material layer is in direct contact with the first conductive layer;
forming a hole (46) in the material layer, wherein the hole is directly above the trench; and
forming a second conductive layer (50) to fill in the hole.

10. The method of fabricating a deep trench capacitor of claim 9, wherein the material layer comprises epitaxial silicon.

11. The method of fabricating a deep trench capacitor of claim 9, further comprising before forming the second conductive layer in the hole, forming a collar oxide (48) surrounding the inner sidewall of the hole.

12. The method of fabricating a deep trench capacitor of claim 9, further comprising after forming the material layer, forming a silicon oxide layer (34) and a silicon nitride layer (36) on the material layer.

13. The method of fabricating a deep trench capacitor of claim 12, wherein the hole extends into the silicon oxide layer and the silicon nitride layer.

14. The method of fabricating a deep trench capacitor of claim 13, further comprising after forming the second conductive layer, forming a third conductive layer (52) to fill in the hole within the silicon oxide layer and the silicon nitride layer.

15. The method of fabricating a deep trench capacitor of claim 14, wherein the first conductive layer serve as a top electrode.

16. The method of fabricating a deep trench capacitor of claim 9, wherein the bottom electrode is formed by a gas diffusion process.

17. The method of fabricating a deep trench capacitor of claim 9, wherein the first conductive layer comprises polysilicon and the second conductive layer comprises polysilicon.

18. The method of fabricating a deep trench device of claim 9, wherein the substrate is a semiconductive substrate.
